(19) United States
(12) Patent Application Publication
(10) Pub. No.: US 2010/0116646 A1
(43) Pub. Date: May 13, 2010

(54) A SENSING ELECTRODE FOR PH MEASUREMENT CHIEFLY IN BODILY FLUIDS

(76) Inventor: Jitka Hanzalova, Beroun (CZ)

Correspondence Address: BUCHANAN, INGERSOLL & ROONEY PC, POST OFFICE BOX 1404, ALEXANDRIA, VA, 22313-1404, US

(21) Appl. No.: 12/594,367

(22) PCT Filed: Mar. 31, 2008
(86) PCT No.: PCT/CZ08/00039

§ 371 Date: Oct. 2, 2009

(30) Foreign Application Priority Data
Apr. 4, 2007 (CZ) PV 2007-243

(51) Int. Cl. G01N 27/26; C23C 14/36; C23C 14/34; C23C 14/48

(52) U.S. Cl. 204/192.22; 204/403.01; 204/192.1; 427/523

(57) ABSTRACT

A sensing electrode consisting of electrically nonconductive underlay (1), made up of polymeric matter, with pH sensitive antimony layer (2) deposited onto, which is connected by means of a secondary conductor (3) with a measurement device (6) in a place, which is out of reach of the system, of which pH is measured. A pH sensitive antimony layer (2) of thickness from 1 micrometer to several millimeters is deposited onto a nonconductive underlay (1) by a method where a metal is evaporated under a vacuum—sputtering, magnetron sputtering, radiofrequency sputtering, diode plasma sputtering, cathodic arc evaporation, ion plating, ionization-assisted evaporation, ion implantation or laser alloying. A sensing electrode is, with benefit, a part of a measurement system, consisting of more sensing electrodes, where each of them is, by means of secondary conductor (3), connected with a measuring device (6) to which one reference electrode (5) is connected to.

### TECHNICAL FIELD

The invention relates to a sensing electrode for pH measurement in bodily fluids.

### PRESENT TECHNICAL CONDITIONS

A glass electrode is used for esophageal application only in limited way in reality, because it is difficult to handle and difficult to manufacture. The biggest disadvantage of a glass electrode is high output impedance causing unfavorable ratio of signal to noise. It is expensive ($500) and therefore it is not suitable for a single use. From a hygienic point of view it is better when an electrode is just for one patient—for a single use only.

Generalities of commercially used devices for esophageal pH measurement in last 25 years use a system based on principle of oxidation reduction metal pH electrode, whose measuring part consist of pH sensitive metal and its oxide, mostly antimony. Although the structural design of measuring probes differs from manufacturer to manufacturer, its principle remains the same. The potential between pH sensitive metal (mostly antimony) and reference electrode—placed either in the same catheter or separately on the body surface—is measured by means of an operational amplifier.

The typical example of construction is an electrode consisting of an antimony cylinder. This is a piece of polycrystalline antimony of approximately 1 mm diameter×1 mm thickness, which is either glued by conductive glue or it is soldered to a secondary conductor coming through a catheter.

There are some disadvantages of this electrode:
A. Laborious manufacturing—antimony is not machinable and it is not workable. An antimony cylinder is obtained by casting in a graphite mold or by sucking of the liquid antimony into a glass capillary, consequent breaking the capillary or by glass etching. Electrodes have to be manufactured individually by hand under a microscope.
B. Inaccuracy of measurement during the life of the sensor—the stomach digestive fluid corrodes polycrystalline antimony during the contact of the antimony with stomach fluid. Cracks form among the individual crystals and on the edges of antimony sensor, (their theoretical depth can go as far as to the depth of the cylinder) and the measured solution gets into them. Incorrect measurement can occur as to the effect of contact with a secondary conductor with the measured liquid.
C. Slowing down the pH change response—a measured liquid is difficult to wash out from small cracks. It leads to slowing down of free H+ ions feedback. This consequently leads to low quality results of measured pH. The same error is caused by etching down of the antimony planar electrode, which became an electrode submersed on the bottom of the deep thin canal by this etching. This causes the slowing of pH response in a time frame of minutes. Other random inaccuracies in pH measurement are also caused by difficulty in managing the crystal orientation during fabrication.

Catheters with a monocrystalline antimony pH sensor remove measuring disadvantages of polycrystalline ones, but they are expensive, so they are not for single use. There is still the disadvantage of expensive and difficult hand manufacturing, if not the impossibility, of mass production. Also this type is burdened by errors caused by slowing down the speed of pH change response as a polycrystalline electrode.

Another known measured electrode consists of metal—primary copper—cylinder, galvanically plated by antimony. The disadvantage of this electrode is small reproducibility during its manufacturing. A galvanizing solution consists of many salts, which specifically influence the resulting product. They are mostly different salts of antimony and copper. The copper salts enhance mechanical properties of a product, but at the same time decrease the electrode sensitivity, because the final product does not consist of pure antimony but antimony with copper admixture. The presence of copper salts in the solutions is necessary, there is no metal coating without them. Concentration of these salts changes during the process of galvanization. It is impossible to ensure each batch has absolutely the same chemical composition. This results in varying of absolute measured value of electrodes manufactured in this way between each batch of tenths of mV. Each set of electrodes has quantitatively different contamination. Another principle disadvantage comes during measurement. An electrode consists of two conductive metals—copper as a base and upper layer of antimony. During the contact with digestion fluids the antimony layer is slowly etched down to copper. This happens mostly by microscopic erosions developing around impurities or other irregularities on the surface of conductive layer. There is a mixture potential between exposed copper and surface antimony, which results in an uncontrollable and unpredictable change of resulting potential of electrodes even during the constant pH of the measured solution. Measured and displayed pH value drifts—even in identical pH solutions. The electrode produces a lower slope and therefore shows smaller change of potential per pH unit.

Eliminating production problems during galvanic coating solves issues described in the international patent WO 02071047, of the sensing electrode composed from a copper conductor with an antimony coating sputtered or evaporated onto its surface. There is better product uniformity, but the main disadvantage of a system that has two conductive metals is still there. Even the small surface flaw, crack caused by strain, mechanical scratch, deficient homogeneity of metal coating and also mutual diffusion of these two metals cause the liquid to be measured is in contact not only with antimony but also with metal base and results in a potential that is incorrect combination of these two potentials. In addition, this ratio of potentials will change during the time span and the electrode will show pH drift even in a solution with constant pH. The unstable electrodes are difficult to properly calibrate.

It is necessary to calibrate each of the above described electrodes in two pH solutions. Some errors, primarily these influencing gain and absolute value of reading, are possible to compensate for by a two-point calibration. However, this is not true for the errors changing during the time span. In addition a calibration is a time (and therefore money) demanding procedure, which has to be done by trained staff.

Another sensing electrode is an electrode from Japanese authors JP 5023360, U.S. Pat. No. 5,573,798, U.S. Pat. No. 5,480,534, EP 0472398 and EP 0472396. A sensing electrode consists of electrically conductive material with nonconductive film thereonto. A part of the nonconductive film is removed and there is a layer of pH sensitive film (a mixture of metal, primarily iridium and its oxide) deposited on the exposed surface. Iridium and its oxide are in contact with electrically conductive material. In addition, the metal oxide layer could be covered by porous, nonconductive material to protect the oxide layer. Also iridium and its oxide are in the some cases deposited directly on nonconductive base, sapphire or ceramics.

There is iridium oxide used in these patents as a pH sensitive layer. The price of iridium is approx. 55 times more expensive than the price of antimony. Sputtering of iridium is problematic because of its reactivity. Pure oxygen is blasted into the evacuated chamber under a controlled pressure to make a coat of metal and metal oxide at the same time and in a specified narrow ratio. A change in the ratio influences the performance of the electrode. A coat of porous, nonconductive material can make worse the access of the measured liquid to the electrode. It also worsens the out-washing of measured solution from porous material and slows down the H+ response. The fast time response is important for the esophageal application, because evaluation of the procedure is based on the time ratio when pH in the esophagus is over or below pH level of 4.

It is not suitable to use ceramics nonconductive underlay for pH measurement in bodily fluids because of possible chipping of the underlay and health hazard of the patient.

### FUNDAMENTALS OF THE INVENTION

A sensing electrode consists of electrically nonconductive underlay material, made up of polymeric matter, with pH sensitive antimony layer which is, by means of secondary conductor, connected to a measuring device, in a place, which is beyond reach of system of which pH is measured.

A nonconductive underlay material is formed from polymeric substance selected from the group consisting of e.g. polycarbonate, polyethylene, polypropylene, polystyrene, or their copolymers.

Also a nonconductive underlay is formed from electron and ion nonconductive organic materials selected from the group consisting of polymer gels or modified cellulose.

The nonconductive underlay has preferable outer shape of hollow cylinder with thickened part in the shape of a ring or a sphere.

A pH sensitive antimony layer is deposited onto the nonconductive underlay by a method where a metal is evaporated under a vacuum—sputtering, magnetron sputtering, radiofrequency sputtering, diode plasma sputtering, cathodic arc evaporation, ion plating, ionization-assisted evaporation, ion implantation or laser alloying.

A pH sensitive antimony layer of thickness from 1 micrometer to 5 millimeters is deposited onto the nonconductive underlay by a magnetron sputtering, under vacuum and in an atmosphere of an inert gas, mostly argon.

A secondary conductor is selected from electrically conductive materials from the group consisting of Cu, Al, Ni, Ag, Au, Pt in a shape of a wire or by a carbon fiber or a conductive liquid, a foam or a gel filling up the inside of catheter.

A pH sensitive antimony layer is connected with a secondary conductor in place, which is insulated from the measured liquid, by means of simply creating compression force in between conductor and sensitive surface, by using conductive spring, conductive glue, or metal plating.

A sensing electrode consists, with benefit, of an underlay in the shape of a hollow cylinder where part of it is widened into the shape of a ring or a sphere and it is coated by an antimony layer on its surface. The secondary conductor comes down through the tube lumen and it is connected at one side with a part of antimony layer placed on the underlay surface. This part of underlay is sealed by an elastic flexible tube, which prevents penetrating of measured liquid to the connection of the secondary conductor with the antimony layer. The antimony layer located on the widened part of underlay in the shape of a ring, is in contact with the measured liquid. The other end of a secondary conductor, coming up through the tube lumen, is together with a second end of the underlay of a cylinder shape, hidden in the second elastic flexible tube, through which it connects to a measuring device. The flexible tubes are with benefit glued to an underlay.

A measuring system for pH measurement in bodily fluids according to this invention can consist of several sensing electrodes, placed above each other, where each of them is by means of secondary conductor connected with a measuring device, to which also one reference electrode is connected.

In accordance with aspect of the present invention the system guarantees accurate results during the entire measuring time. Even after the partial etching down of pH sensitive antimony layer from a surface of nonconductive underlay, the electrochemical potential between an antimony layer and measured bodily fluid is very stable.

Manufacturing of a sensing electrode according to the invention is, in comparison with currently known electrodes, much easier, has good reproducibility, and is inexpensive to make. It also enables miniaturization of the electrode. A nonconductive underlay of plastic is easy to press or mold into the desired shape. This removes a disadvantage of difficult workability and mach inability of a pH sensitive metal—e.g. antimony. There is a possibility to deposit a conductive metal by means of, for example, sputtering under a vacuum on the surface of small plastic pressing or molding. Each sputtering batches can accommodate hundredths of thousands of pieces (moldings) at a time. After the end of the sputtering process, but at the least during the first minute in measured solution, the equation of metal/metal oxide is set up in antimony layer by itself.

Similarly it is possible to deposit, on nonconductive underlay, any pH sensitive metal, chosen from the group of metals measuring pH, which are based on a change of their oxidating degree according to an equation:

MₓO_{y}+2y(e⁻+H⁺)=xM+yH₂O

or according to the equation

2MO_{y}+2H⁺+2e⁻=(2y−1)M₂O+H₂O.

Nevertheless antimony is the most used metal from the first group. It is easy to sputter it on nonconductive underlay and it creates required balance of metal/metal oxide.

Also it is possible to easily automate manufacturing processes. High reproducibility of manufacturing concerning all the important parameters (offset, gain, drift and lifetime) eliminates cumbersome and expensive calibration, which is necessary to perform with all existing electrodes directly by the medical user when it is set up. This calibration takes up to 70% of time given to a patient in contemporary measuring systems. The calibration itself during set up is difficult and problematic, thanks to necessary training of medical staff and buffer instability due to uncontrolled temperatures. Experience shows, that these variables can cause error up to one pH, which can influence the result of an examination. If we add also drift during tens of hours of use, these results in high inaccuracy. Some companies consider it necessary to calibrate their devices again after patients use, to eliminate at least some of errors of measurement. An advantage of sensing electrodes according to this invention is that the electrodes do not require calibration of each single electrode.

Electrodes manufactured according to this invention are intended for single use. Through controlling the thickness of the conductive metal on the nonconductive underlay it is possible to limit active lifetime of the electrode. This is important particularly from hygienic and safety view and, due to its nature, prevent multiple use of an electrode.

A system according to an invention is possible to use for measuring of pH namely in bodily fluids by means of a catheter.

### FIGURES SUMMARY

FIG. 1—illustration of a sensing electrode

FIG. 2—illustration of a sensing and reference electrode

FIG. 3—illustration of a system with multiple sensing and reference electrode

### DESIGN EXAMPLES

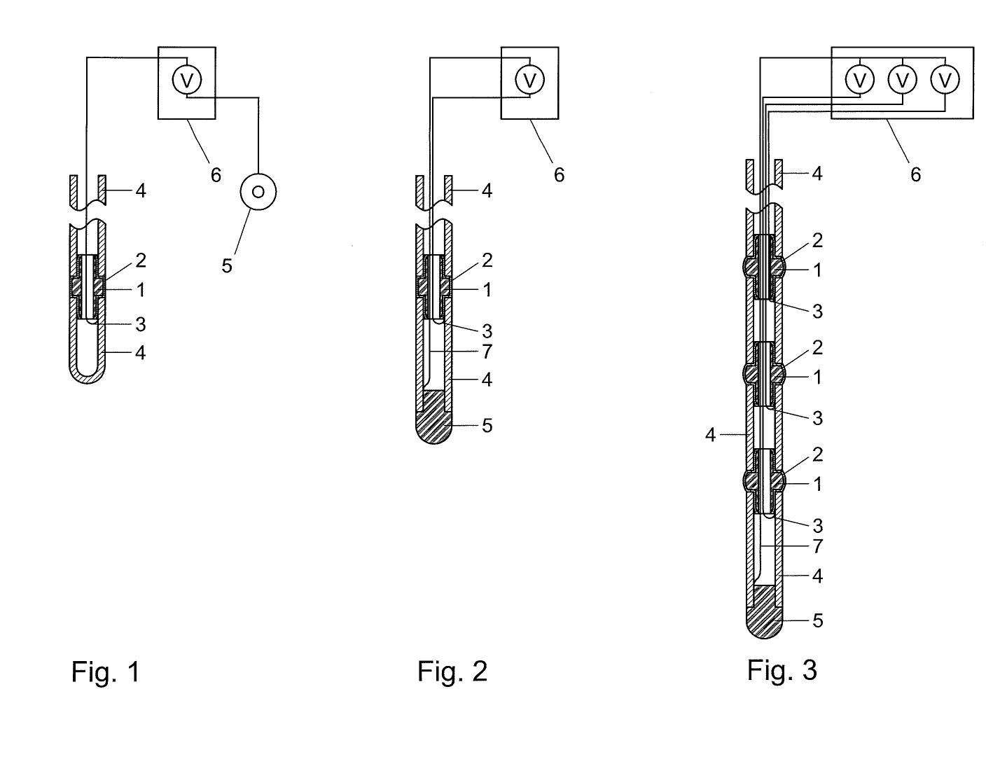

FIG. 1 pictures sensing electrode, consisting of electrically nonconductive body 1, in form of hollow polycarbonate cylinder 7 mm long. The cylinder is wider in the middle—the diameter of this middle section is 2 mm and length is 3 mm and represents about ⅓ of the total cylinder length.

The thicker middle part in the shape of cylinder or sphere has the best surface to volume ratio. H+ ion diffusion increases, current density is higher, which results in a stable reading at measuring device 6.

The area between the tube 4 and pH sensitive antimony layer 2 is problematic in all current designs and potentially in this design as well, since in this area a slower washing-out of a measured solution can occur, resulting in slower pH response. This problem is eliminated to great extent due to the small percentage of this region. The total area of antimony layer 2 is much bigger then the problematic edge area even in miniature catheter design of 1-2 mm in diameter.

An electrode according to the invention with circular pH sensitive antimony area 2 does not suffer from false reading due to an attachment to an esophagus wall, which an electrode with flat sensitive area may exhibit, when a measured liquid cannot reach the sensitive surface.

The whole surface of the body 1 is covered by an electrically conductive, pH sensitive layer of antimony 2. The antimony layer of 99.99% purity and 9 micrometer thickness is sputtered in a planar magnetron with double rotation in argon inert atmosphere of pressure 100 militorr and cathode potential −1 kV. The antimony in layer 2 forms metal/oxide equilibrium spontaneously after the deposition when placed in free air or during the first minutes of measurement in a solution.

The antimony layer 2 is connected to a secondary wire conductor 3, which is placed in the body hollow 1 and its non-insulated tip goes onto the distal part of the body 1. A flexible polyurethane tube 4 of outer diameter 2 mm is placed over this end of the body and presses the wire 3 against the antimony layer 2. Another piece of flexible polyurethane tube 4 is placed over the proximal end of the body 1 and the insulated secondary conductor 3 goes through the tube 4 to the measuring device 6. The antimony layer 2 on the thicker part of the body 1 has a ring shape and it is in contact with the measured solution. Tubes 4 are glued to the body 1.

The sensing electrode according to this invention allows a modular design of a catheter where multiple active electrodes (modules) can be easily placed above each other in the same catheter.

There are possible options, where also reference Ag/AgCl electrode 5 is placed in polyurethane tube 4 in similar manner. In this case insulated conductor 7 also goes through hollow of body 1 and connects reference electrode 5 with the measurement device 6. A reference electrode 5 could also be external—placed utterly outside of catheter.

FIG. 2 illustrates reference electrode 5 connected by insulated conductor 7, which goes through first tube 4, hollow of underlay 1 and the second tube 4 and it is connected to a measuring device 6. Reference electrode 5 is tightened by first flexible polyurethane tube 4 and this connection is secured by glue. Measuring part of reference electrode 5 blocks up interior space of the first polyurethane tube 4 at its distal end and obstructs the entering of the liquid of which pH is measured into this area. Another alternate is the placement of a reference electrode 5 at any position in the catheter, where a reference electrode is sealed up by a polyurethan tube 4, the joint is secured by a glue and a measuring part of a reference electrode 5 is in contact with liquid which pH is to be measured. Distal end of a catheter is sealed up by the first polyurethane tube 4 with sealed end.

Contact areas between underlay 1 and tube 4 are glued by UV curable epoxy in the way, that there is no leak in the vicinity of underlay 1, so no measured liquid could exist here. Liquid in such a cavity would lead to faulty wash out of a liquid and slowing down the pH response. Another reason is to protect accidental intrusion of a liquid to a secondary conductor 3 and also to increase catheter's pulling strength. An electrode constructed in this manner sustained in buffer pH=7 more than 24 hours had a drift of less than 5 mV/24 hours. By contrast, electrodes manufactured by electrochemical way on the copper base have drift from 15 to 20 mV during one hour and antimony casted electrodes have drift from 15 to 25 mV/24 hours.

FIG. 3 demonstrates design of the system for pH measurement with more sensing electrodes, where pH measurement is carried on at more locations in the esophagus at the same time. Nonconductive underlay 1 of sensing electrode is in a shape of hollow polycarbonate cylinder thickened in the middle into a sphere shape. FIG. 3 illustrates placing and interconnection of several sensing electrodes (modules) above each other connected to a measuring device 6, where every single electrode is connected with measuring device 6 by means of its own secondary conductor 3. There is also one reference electrode 5 connected to the measuring device 6. The utilization of this system is a more accurately measurement of the ascending level of stomach fluid in esophagus.

Esophageal reflux (effusion of HCl from stomach in esophagus area) occurs upon insufficient closing of lower esophageal sphincter, placed between esophagus and stomach. Quantity of freed HCl is measured by catheter, with one or more pH electrodes, placed through the nose into the esophagus and placed above lower esophageal sphincter.

Unlike contemporary manufacturing technologies of sensing electrodes, this system of modular catheter allows the important advantage of easy assembly and a cost price of a multiple-electrode catheter much lower than existing catheters. It will also be easy to make special catheters according to a doctor's specifications. Because of the lower price of multiple sensor catheters, a doctor can use it in the first visit to evaluate not only qualitative, but also quantitative status of a patient. A big relief for a patient is using of a price reasonable modular—multiple electrode—catheter as early as the first 24 hours stating measurement of closing of esophageal sphincter. Presently the basic 24 hours measurement of esophageal reflux is carried on by a catheter with one electrode placed 5 cm above the esophageal sphincter, because of its lower price. If it is verified that a patients problems are caused by insufficient closing of lower esophageal sphincter characterized by regurgitation of HCl into esophagus, there is a need to know a reflux volume i.e. height level, by 24 hour surveying with a more expensive, multiple-electrode catheter. An adult human esophagus is from 20 to 24 cm long, which means a catheter with four sensors placed 4-5 from each other is chosen. This spot is specified in accordance with patients needs by other catheters tailored to a patient. Multiple measurement is displeasing for the patient—the catheter is inserted into the esophagus through the nose, from which it connects to an external portable voltmeter with recording system and remains during the entire recording time. As for the medical staff—there are necessary repetitive patients visits and treatment is more expensive. Manufacturing and use of a multiple-electrode catheter according to this invention will be similar in cost to a simple single one, so its application can be placed during the first patients visit. To prepare custom-made catheter will be similarly easy as the basic catheter. This modular system is easily personalized to the particular demands of a patient. In the case of a child with a shorter esophagus, all measured electrodes could be placed along the length of 8 cm, for example. It is possible to easily manufacture a custom-made catheter made-to-measure for a patient with difficulties in a certain part of esophagus.

### UTILITY OF THE PATENT

A sensing electrode according to invention can be used mainly for continuous measurement of pH in the case of esophageal reflux. In light of its possible miniaturization and possibility to building-in catheters, it is suitable for using in medicine, for pH measurement of bodily fluids. There are other applications where existing antimony pH electrodes are used. For example in determination of pH of drinking water, for checking of pH of cosmetic products or for monitoring of pH during certain chemical or food processes and others.

1. A sensing electrode for pH measurement primarily in bodily fluids, distinguishing itself by consisting of electrically nonconductive underlay, with pH sensitive layer deposited onto, characterized herewith, that electrically nonconductive underlay is formed from polymeric material selected from the group consisting of e.g. polycarbonate, polyethylene, polypropylene, polystyrene, or their copolymers or modified cellulose and the pH sensitive layer is antimony layer which is connected by means of a secondary conductor with measurement device in a place, which is out of reach of the liquid system, of which pH is measured, whereas an nonconductive underlay has a shape of hollow cylinder thickened in its part into a shape of a ring or a sphere.

2. An electrode according to claim 1, wherein the pH sensitive antimony layer is deposited onto nonconductive underlay by method, where a metal is evaporated under a vacuum—sputtering, magnetron sputtering, radiofrequency sputtering, diode plasma sputtering, cathodic arc evaporation, ion plating, ionization-assisted evaporation, ion implantation, or laser alloying.

3. An electrode according to claim 1, wherein the antimony layer of thickness from 1 micrometer to 5 millimeters is deposited by magnetron sputtering onto the underlay in vacuum in an atmosphere of an inert gas, mostly argon.

4. An electrode according to claim 1, wherein the secondary conductor is selected from electrically conductive materials selected from the group consisting of Cu, Al, Ni, Ag, Au, Pt in a shape of a wire, by a carbon fiber, by a conductive liquid, by a foam, or by a gel filling up the inside of catheter.

5. An electrode according to claim 1, wherein the pH sensitive antimony layer is connected with a secondary conductor in a place, which is distal to the measured liquid by means of pressing, by conductive spring, by gluing by conductive glue, or by metal plating.

6. An electrode according to claim 1, wherein the nonconductive underlay is made of polycarbonate having a shape of hollow cylinder where its part is widened into a shape of a ring or a sphere, is coated by an antimony layer on its surface, where the secondary conductor comes down through the underlay hollow and is conducted away at one side from the underlay hollow and is connected with part of antimony layer placed on the underlay surface, where this part of underlay is overlapped by first elastic flexible tube, which prevents intrusion of measured liquid to the connection of the secondary conductor with the antimony layer and the antimony layer located on the widened part of underlay in the shape of a ring, is in contact with measured liquid and the other end of a secondary conductor, going up through the cylinder hollow, is together with a second end of the underlay, of a cylinder shape, constricted in the second elastic flexible tube through which it gets along, towards to a measuring device.

7. A measuring system for pH measurement in bodily fluids consisting of sensing electrodes according to claim 1 placed above each other, where each of sensing electrodes is by means of its own secondary conductor connected with a measuring device to which one reference electrode is connected.
